(19) United States
(12) Patent Application Publication
(10) Pub. No.: US 2010/0091830 A1
(43) Pub. Date: Apr. 15, 2010

(54) EQUALIZER AND METHOD FOR CONFIGURING THE EQUALIZER

(76) Inventors: Yi-Lin Li, Kao-Hsiung City (TW); Cheng-Yi Huang, I-Lan Hsien (TW)

Correspondence Address: NORTH AMERICA INTELLECTUAL PROPERTY CORPORATION, P.O. BOX 506, MERRIFIELD, VA, 22116, US

(21) Appl. No.: 12/578,555

(22) Filed: Oct. 13, 2009

(30) Foreign Application Priority Data
Oct. 13, 2008 (TW) 097139171

(51) Int. Cl. H03H 7/30

(52) U.S. Cl. 375/231; 375/232

(57) ABSTRACT

An equalizer includes a tapped delay line and an adder. The tapped delay line includes a plurality of taps cascaded to each other. The tapped delay line receives an input signal, a plurality of tap control signals, and a plurality of tap coefficients and generates a plurality of multiplied signals. The plurality of taps is divided into a plurality of groups. The adder is coupled to the tapped delay line for adding the plurality of multiplied signals up to generate an output signal.

### BACKGROUND OF THE INVENTION

1. Field of the Invention

The present invention relates to an equalizer and a related method, and more particularly, to an equalizer having a hybrid architecture and a related method.

2. Description of the Prior Art

When signals are transmitted in communication systems, the signal attenuation and inter-symbol interference (ISI) will become more serious along with the increase of the channel length, which reduces the signal quality. Hence, an equalizer is usually disposed in the signal receiver for equalizing the received signals to compensate for the signal attenuation and to solve the ISI issue.

At present, common equalizers contain liner feed-forward equalizers (LE) and decision feedback equalizers (DFE). The DFE further comprises a feed-forward filter and a feedback filter. The feed-forward filter among the LE and the DFE is implemented by a weighted sum of the sampling data with equal time-interval, which is herein called an equally-spaced equalizer. The common equally-spaced equalizer is further divided into a symbol-spaced equalizer and a fractionally-spaced equalizer, wherein the performance of the fractionally-spaced equalizer is better than that of the symbol-spaced equalizer and is less affected by the timing phase offset. But the fractionally-spaced equalizer has the disadvantages of instability, large power consumption, and great complexity.

### SUMMARY OF THE INVENTION

It is therefore one of the objectives of the claimed invention to provide an equalizer and a method for configuring the equalizer, which controls the sampling interval of the equalizer according to the characteristic (such as tap coefficient) of each tap among the equalizer to solve the abovementioned problems.

According to the present invention, an equalizer is provided. The equalizer includes a tapped delay line having a plurality of taps cascaded to each other and an adder. The tapped delay line receives an input signal and generates a plurality of multiplied signals, wherein the plurality of taps are divided into a plurality of groups. The adder is coupled to the tapped delay line for adding the plurality of multiplied signals to generate an output signal.

According to the present invention, a method for configuring an equalizer is provided. The equalizer includes a tapped delay line formed by a plurality of taps cascaded to each other and an adder. The method includes the steps of dividing the plurality of taps into a first group and a second group, wherein a first sampling interval of the first group is different from a second sampling interval of the second group; and adding a plurality of multiplied signals generated by the plurality of taps to generate an output signal.

According to the present invention, another method for configuring an equalizer is provided. The equalizer includes a tapped delay line formed by a plurality of taps cascaded to each other and an adder. The method includes the steps of dividing the plurality of taps into at least one group; disabling any one tap of the plurality of taps among the at least one group according to a tap coefficient; and adding a plurality of multiplied signals generated by the non-disabled taps of the plurality of taps among the at least one group to generate an output signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of an equalizer according to a first embodiment of the present invention.

FIG. 2 is a diagram of an equalizer according to a second embodiment of the present invention.

FIG. 3 is a diagram of an equalizer according to a third embodiment of the present invention.

FIG. 4 is a diagram of an equalizer according to a fourth embodiment of the present invention.

FIG. 5 is a diagram of an equalizer according to a fifth embodiment of the present invention.

FIG. 6 is a diagram of an equalizer according to a sixth embodiment of the present invention.

### DETAILED DESCRIPTION

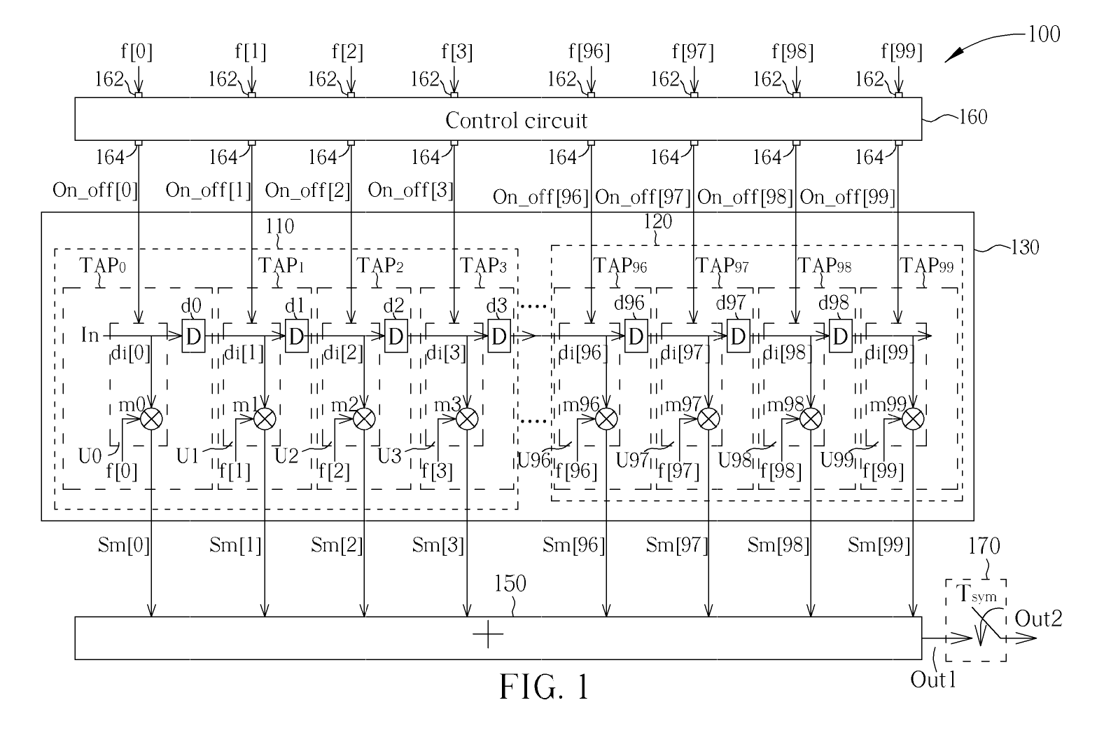

Please refer to FIG. 1. FIG. 1 is a diagram of an equalizer 100 according to a first embodiment of the present invention. In this embodiment, the equalizer 100 is a tapped delay line equalizer. and the equalizer 100 includes, but is not limited to, a tapped delay line 130, an adder 150, a control circuit 160, and a switch 170. The tapped delay line 130 comprises a plurality of taps TAP₀˜TAP₉₉ cascaded to each other, wherein the taps TAP₀˜TAP₉₉ are divided into a first group 110 and a second group 120 based on demands. A first sampling interval T₁ of the first group 110 is equal to a symbol period T_{sym} of an input signal In (i.e., T₁=T_{sym}), and a second sampling interval T₂ of the second group 120 is smaller than the symbol period T_{sym} of the input signal In (i.e.,

$${T}_{2} = \frac{{T}_{sym}}{R} < {T}_{sym} ,$$

wherein R is a rational number greater than 1) to avoid insufficient sampling data. In this embodiment, one hundred taps TAP₀˜TAP₉₉ are taken as an example, but this is merely an example for illustrating the present invention and the number of the taps should not be considered as a limitation of the present invention. Each of the taps TAP₀˜TAP₉₉ comprises a tap unit U0˜U99 and a delay unit d0˜d98, wherein each tap unit includes a signal input terminal, a multiplier, and a control terminal. For example, the signal input terminal of the first tap unit U0 receives an input signal di[0] of the first tap TAP₀, and the first multiplier m0 multiplies the input signal di[0] of the first tap TAP₀ by a tap coefficient f[0] to generate a multiplied signal Sm[0]. The control terminal of the first tap unit U0 determines to enable or disable the first tap unit U0 according to a control signal On_off[0]. The delay unit d0 is coupled between the tap unit U0 and the next tap unit U1 for delaying the input signal di[0] of the first tap TAP₀, so as to generate the input signal di[1] of the next tap TAP₁. The rest may be deduced by analogy.

Be noted that the configurations of the first group 110 and the second group 120 are not fixed. In this embodiment (referred to FIG. 1), the first group 110 comprises the taps TAP₀˜TAP₉₅ and the second group 120 comprises the taps TAP₉₆˜TAP₉₉, but this should not be considered as the only way for configuring the groups. In other words, the taps among each group need not be divided in accordance with the order, and the taps included by the groups can be interwoven. For example, in other embodiments (not shown), the first group 110 can comprise the taps TAP₀, TAP₃, TAP₈, TAP1₀, . . . , TAP₉₇, and TAP₉₉, and the second group can comprise the taps TAP₁, TAP₂, TAP₄, TAP₅, TAP₇, TAP₉, . . . , TAP₉₆, and TAP₉₈. Therefore, the taps among the first group 110 and the second group 120 are interwoven. In addition, the taps among the first group 110 and the second group 120 are configured by the control circuit 160 in a dynamically-configured manner according to tap coefficients based on channel estimation or an adaptive algorithm. The control circuit 160 includes at least an input terminal 162 and a plurality of output terminals 164, wherein the input terminal 162 receives at least an information. For example, the input terminals 162 are used for receiving the plurality of tap coefficients f[0]˜f[99] in this embodiment. The plurality of input terminals 164 is coupled to the plurality of control terminals of the tap units U0˜U99 for generating the plurality of control signals On_off[0]˜On_off[99] to the tap units U0˜U99 according to tap coefficients f[0]˜f[99], so as to determine to enable or disable the corresponding tap units. The adder 150 comprises a plurality of input terminals coupled to the plurality of taps TAP₀˜TAP₉₉ for adding the plurality of multiplied signals Sm[0]˜Sm[99] to generate an output signal Out1. The switch 170 is coupled to the output terminal of the adder 150 for outputting the output signal Out1 whenever a symbol period T_{sym} passes through to generate a controlled output signal Out2.

Please note that, since the first sampling interval T₁ of the first group 110 is equal to the symbol period T_{sym} of the input signal In and the second sampling interval T₂ of the second group 120 is smaller than the symbol period T_{sym} of the input signal In, the first group 110 can be viewed as a symbol-spaced equalizer and the second group 120 can be viewed as a fractionally-spaced equalizer.

Following the embodiment (please keep referring to FIG. 1) above, some examples are taken for illustration. Assume that the delay time of two delay units equals the symbol period T_{sym} of the input signal In, and the tap units with an even number (i.e., U0, U2, U4 . . . ) among the first group 110 are disabled and the tap units with an odd number (i.e., U1, U3, U5 . . . ) among the first group 110 are enabled. Therefore, only the multiplied signals (i.e., Sm[1], Sm[3], Sm[5] . . . ) of the tap units with the odd number among the first group 110 will be transmitted to the adder 150 to be added, so that the first sampling interval T₁ of the first group 110 is equal to the symbol period T_{sym}, that is, the delay time of two delay units. On the other hand, also assume that the delay time of two delay units equals the symbol period T_{sym} of the input signal In, and all the tap units among the second group 120 are enabled. Therefore, all the multiplied signals generated by the second group 120 will be transmitted to the adder 150 to be added, so that the second sampling interval T2 of the second group 120 is equal to a half of the symbol period T_{sym}, that is, the delay time of one delay unit

$$( T 2 \frac{{T}_{sym}}{2} , R = 2 ) .$$

The abovementioned embodiments are presented merely for describing the present invention, and should not be considered as limitations of the present invention. In other embodiments, the first sampling interval T₁ and the second sampling interval T₂ with various values can be adopted to implement the equalizer disclosed in the present invention, which should also belong to the scope of the present invention. For example, assume that the delay time of three delay units equals the symbol period T_{sym} of the input signal In. Thus only one tap unit of every three tap unit among the first group 110 is enabled, and the other two tap units are disabled. In other words, only the tap units U2, U5, U8 . . . among the first group 110 are enabled and the other tap units among the first group 110 are disabled, so that the first sampling interval T₁ of the first group 110 is equal to the symbol period T_{sym} (i.e., the delay time of three delay units). On the other hand, assume that the delay time of three delay units equals the symbol period T_{sym} of the input signal In. All the tap units among the second group 120 are enabled, so that the second sampling interval T2 of the second group 120 is equal to one-third of the symbol period T_{sym} (i.e., the delay time of one delay unit).

Be noted that the abovementioned tap coefficients f[0]˜f[99] can be generated based on channel estimation or an adaptive algorithm, but those skilled in the art should appreciate that they can be generated by adopting other manners. In addition, in one embodiment, the equalizer 100 can be a liner feed-forward Equalizer (LE) or a decision-feedback equalizer (DFE). But the present invention is not limited to this only and can be an equalizer of other types.

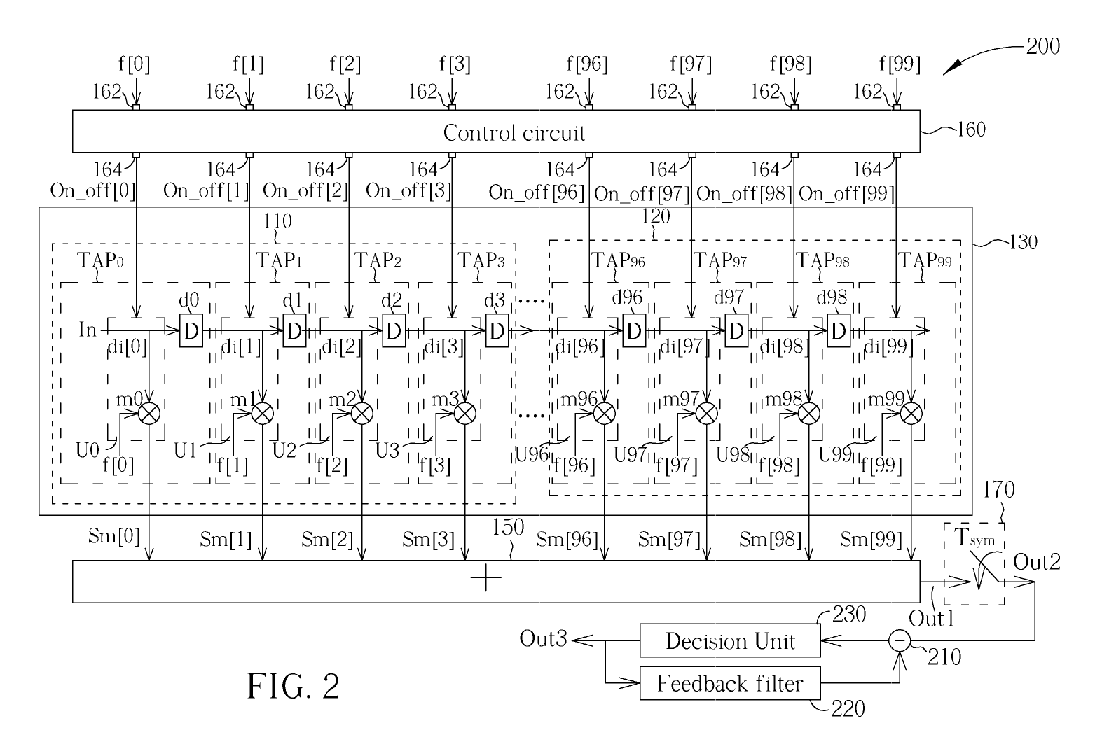

FIG. 2 is a diagram of an equalizer 200 according to a second embodiment of the present invention. The architecture of the equalizer 200 shown in FIG. 2 is similar to that of the equalizer 100 shown in FIG. 1, and the difference between them is that the equalizer 200 is implemented by a decision-feedback equalizer (DFE) but the equalizer 100 is implemented by a liner feed-forward Equalizer (LE). Be compared with them, the equalizer 200 further comprises a subtractor 210, a feedback filter 220, and a decision unit 230 coupled to the back-end of the switch 170. As details and operations of the subtractor 210, the feedback filter 220, and the decision unit 230 are commonly known to those skilled in the art, therefore the description is omitted here for the sake of brevity.

In the embodiments above, the configurations of the first group 110 and the second group 120 are unfixed and can be determined by the control circuit 160 in a dynamically-configured manner, but this should not be considered as limitations of the present invention. Since the channel characteristics can be easily predicted in some environments (such as LAN or cable), the characteristics of the equalizers 100 and 200 can also be predicted easily. Hence, in such environments, the equalizer can be configured in advance to determine which taps can be equalized by using the symbol-spaced equalizer and which taps can be equalized by using the fractionally-spaced equalizer based on these predicted characteristics.

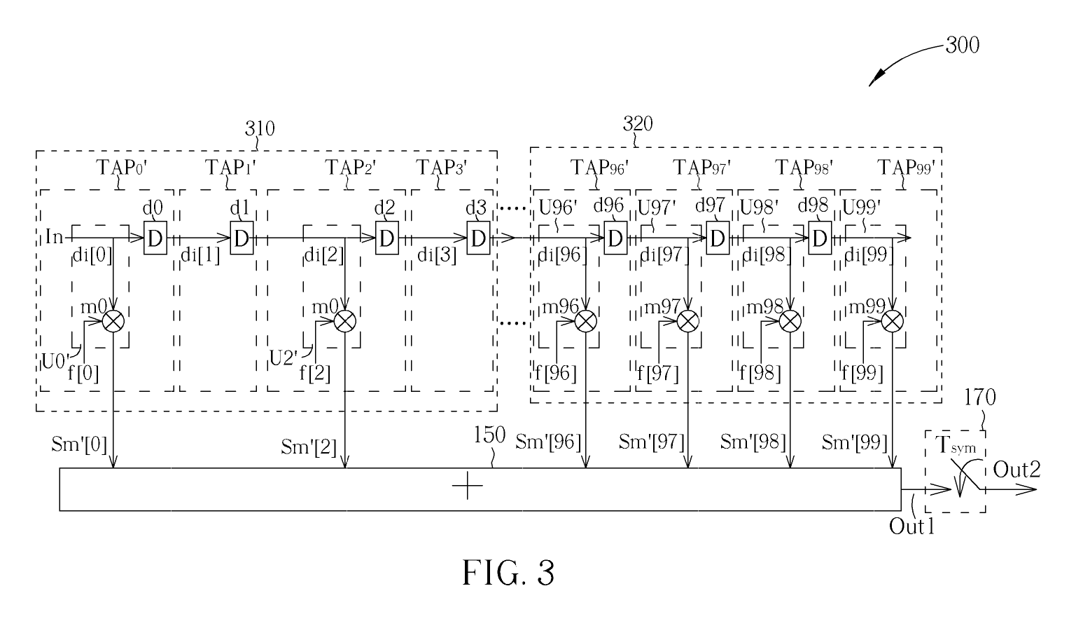

FIG. 3 is a diagram of an equalizer 300 according to a third embodiment of the present invention. In this embodiment, a first group 310 and a second group 320 of the equalizer 300 are configured in advance according to the predicted characteristics of the equalizer 300. Be compared with the equalizer 100 shown in FIG. 1, the equalizer 300 does not need the control circuit 160 to generate the plurality of control signals On_off[0]˜On_off[99] to the tap units U0′˜U99′ for determining to enable or disable the corresponding tap units. Be note that, due to the second group 320 being used as a fractionally-spaced equalizer, the architecture of the second group 320 is totally identical to the second group 120 of the equalizer 100. Each tap (i.e., TAP₉₆′, TAP₉₇′ . . . ) among the second group 320 comprises a tap unit and a delay unit. In contrast, due to the first group 310 being used as a symbol-spaced equalizer, each of the tap units with an even number (i.e., TAP₀′, TAP₂′, . . . ) among the first group 310 comprises a tap unit and a delay unit while each of the tap units with an odd number (i.e., TAP₁′, TAP₃′, . . . ) among the first group 310 only comprises a delay unit.

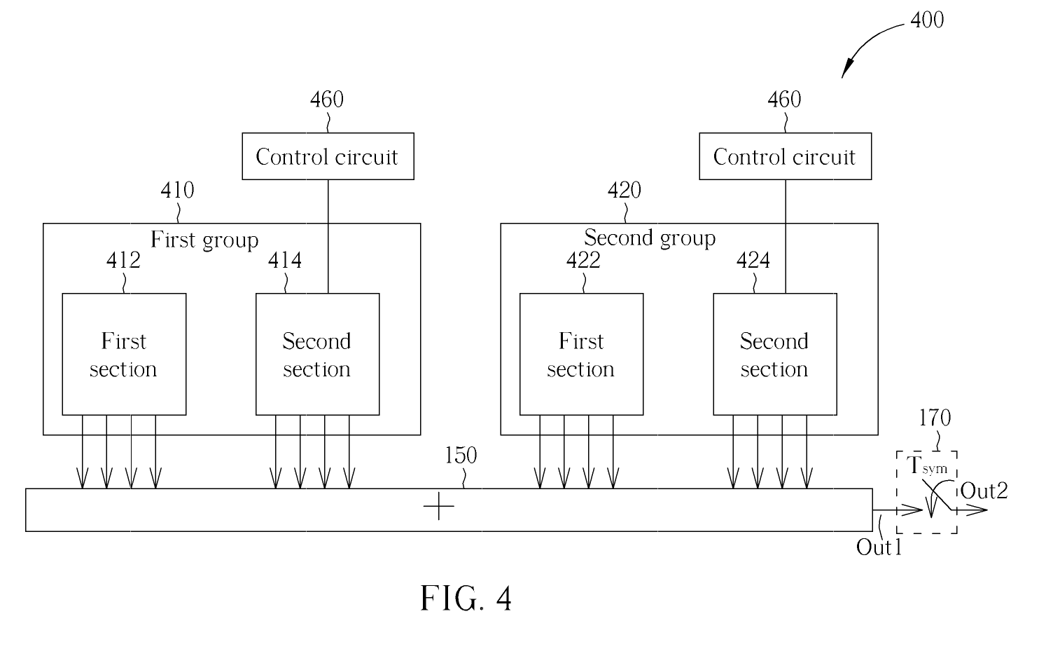

FIG. 4 is a simplified diagram of an equalizer 400 according to a fourth embodiment of the present invention. In this embodiment, the configurations of the taps among a first section 412 of a first group 410 of the equalizer 400 and a first section 422 of a second group 420 of the equalizer 400 are fixed, while the configurations of the taps among a second section 414 of the first group 410 and a second section 424 of the second group 420 are unfixed. In other words, the equalizer 400 adopts a hybrid architecture by merging the equalizer 100 and the equalizer 300. Only the taps among the second groups 414 and 424 need to be configured by collocating the control circuit 460, and the taps among the first sections 412 and 422 can be configured in advance based on the predictable characteristics of the equalizer 400.

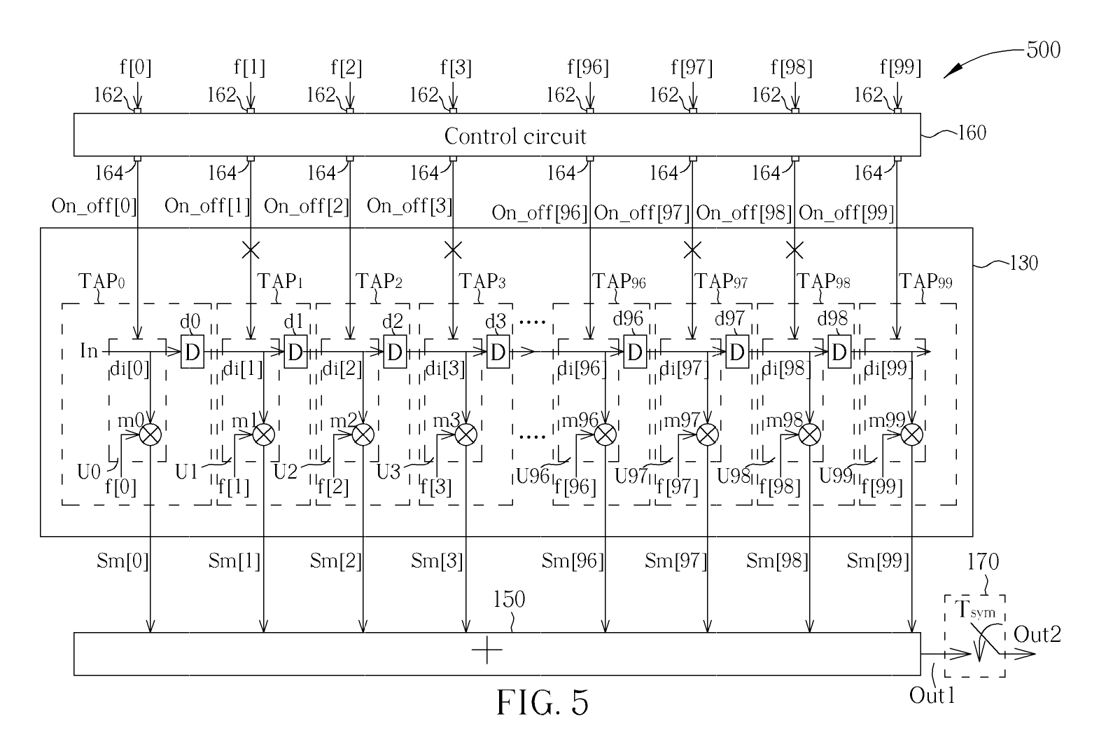

FIG. 5 is a diagram of an equalizer 500 according to a fifth embodiment of the present invention. The architecture of the equalizer 500 is similar to the equalizer 100 shown in FIG. 1, and the difference between them is that these taps TAP₀˜TAP₉₉ among the equalizer 500 are not advisedly divided into several groups, and which taps are configured and determined to be enabled or disabled directly based on the plurality of tap coefficients f[0]˜f[99] received by the control circuit 160. Here, the whole tapped delay-line 130 can be viewed as a single group. That is to say, the disabled manner to the taps is not limited, and these taps can be continuously enabled/disabled. Arbitrary numbers of disabled taps can be connected in-between two enabled taps, or arbitrary numbers of enabled taps can be connected in-between two disabled taps. For example, as shown in FIG. 5, the tap units TAP₁, TAP₃, TAP₉₇, and TAP₉₈ are disabled while all the other tap units are enabled.

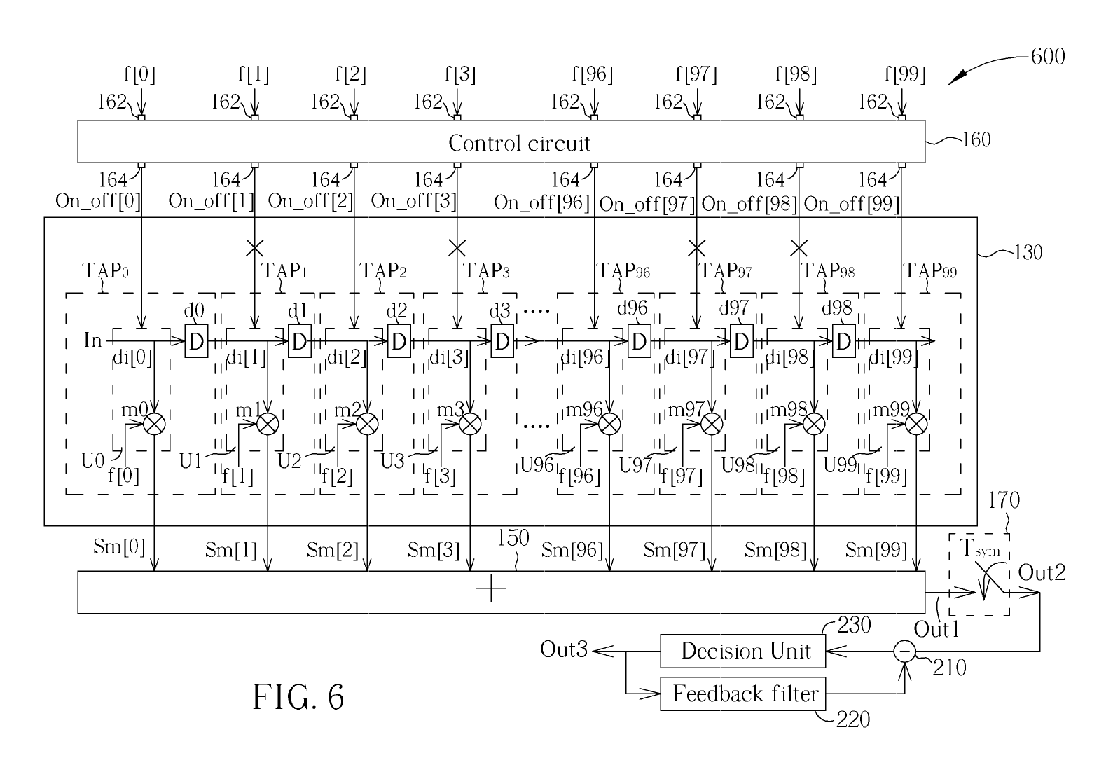

FIG. 6 is a diagram of an equalizer 600 according to a sixth embodiment of the present invention. The architecture of the equalizer 600 is similar to the equalizer 200 shown in FIG. 2, and the difference between them is that these taps TAP₀˜TAP₉₉ among the equalizer 600 are not advisedly divided into several groups, and which taps are configured and determined to be enabled or disabled according to the same configuring manner adopted in FIG. 5.

Be noted that, no matter the taps of the first group (i.e., the symbol-spaced equalizer) and the second group (i.e., the fractionally-spaced equalizer) are configured by adopting a predetermined manner, a dynamically-configured manner, or a mixed manner, which should also belong to the scope of the present invention.

The abovementioned embodiments are presented merely for describing the present invention, and in no way should be considered to be limitations of the scope of the present invention. In summary, the present invention provides an equalizer capable of configuring the taps in a dynamically-configured manner or a predetermined manner based on the characteristics of each tap (such as the equalizer coefficients), so that the input signals of each tap can be equalized according to different coefficients. Hence, if the tap coefficient is expected to be smaller, the symbol-spaced equalizer implemented by the first group is adopted; if the tap coefficient is expected to be larger, the fractionally-spaced equalizer implemented by the second group is adopted. In this way, the equalizer with a hybrid architecture disclosed in the present invention can possess both the advantages of the symbol-spaced equalizer and the fractionally-spaced equalizer, so that not only can the efficiency be improved but also can the goal of lowering cost and reducing power consumption be achieved.

Those skilled in the art will readily observe that numerous modifications and alterations of the device and method may be made while retaining the teachings of the invention.

What is claimed is:

1. An equalizer, comprising:
a tapped delay line, comprising a plurality of taps cascaded to each other, for receiving an input signal and for generating a plurality of multiplied signals, wherein the plurality of taps are divided into a plurality of groups; and
an adder, coupled to the tapped delay line, for adding the plurality of multiplied signals to generate an output signal.

2. The equalizer of claim 1, wherein the plurality of groups comprise a first group and a second group, and a first sampling interval of the first group is substantially equal to a symbol period of the input signal and a second sampling interval of the second group is substantially smaller than the symbol period.

3. The equalizer of claim 1, further comprising:
a control circuit, coupled to the plurality of taps through a plurality of tap control signals, for receiving a plurality of tap coefficients and for dividing the plurality of taps into the plurality of groups according to the plurality of tap coefficients.

4. The equalizer of claim 3, wherein the control circuit generates the plurality of tap control signals according to the plurality of tap coefficients, so as to disable or enable the plurality of taps respectively.

5. The equalizer of claim 3, wherein the plurality of tap coefficients are generated according to channel estimation or an adaptive algorithm.

6. The equalizer of claim 1, wherein the plurality of groups comprise a first group and a second group, the configurations of the first group and the second group are fixed, and each tap is enabled or disabled in advance according to predicted channel characteristics.

7. The equalizer of claim 6, wherein the taps among the first group are further divided into a plurality of first taps and a plurality of second taps, and the first taps are enabled in advance while the second taps are disabled in advance; each first tap comprises a tap unit and a delay unit, and each second tap comprises a delay unit; and every N second taps are coupled in between every two first taps, and N is a positive integer.

8. The equalizer of claim 6, wherein the configuration of a first section of the first group is fixed, and the configuration of a second section of the first group is unfixed.

9. The equalizer of claim 8, further comprising:
a control circuit, coupled to the taps among the second section through a plurality of tap control signals, for receiving a plurality of tap coefficients and for generating a plurality the tap control signals according to the tap coefficients, so as to determine whether to disable the taps among the second section.

10. A method for configuring an equalizer, the equalizer comprising a tapped delay line formed by a plurality of taps cascaded to each other and an adder, the method comprising:
dividing the plurality of taps into a first group and a second group, wherein a first sampling interval of the first group is different from a second sampling interval of the second group; and
adding a plurality of multiplied signals generated by the plurality of taps to generate an output signal.

11. The method of claim 10, wherein the first sampling interval is substantially equal to a symbol period of an input signal, and the second sampling interval is substantially smaller than the symbol period.

12. The method of claim 10, further comprising:
configuring the first group and the second group in a dynamically-configured manner based on channel estimation or an adaptive algorithm.

13. A method for configuring an equalizer, the equalizer comprising a tapped delay line formed by a plurality of taps cascaded to each other and an adder, the method comprising:
dividing the plurality of taps into at least one group;
disabling any one tap of the plurality of taps among the at least one group according to a tap coefficient; and
adding a plurality of multiplied signals generated by the non-disabled taps of the plurality of taps among the at least one group to generate an output signal.

14. The method of claim 13, wherein the step of disabling any one tap of the plurality of taps among the at least one group according to a tap coefficient comprises:
configuring any one tap of the plurality of taps among the at least one group in a dynamically-configured manner based on channel estimation or an adaptive algorithm.

15. The method of claim 13, wherein the step of dividing the plurality of taps into at least one group comprises:
dividing the plurality of taps into a plurality of groups, and the plurality of groups comprises a first group and a second group;
wherein any tap among the first group is different from any tap among the second group.

16. The method of claim 15, wherein the step of disabling any one tap of the plurality of taps among the at least one group according to a tap coefficient comprises:
configuring any one tap of the plurality of taps among the first group in a predetermined manner according to predicted channel characteristics.

17. The method of claim 15, wherein the step of disabling any one tap of the plurality of taps among the at least one group according to a tap coefficient comprises:
configuring any one tap of the plurality of taps among the first group in a dynamically-configured manner based on channel estimation or an adaptive algorithm.

18. The method of claim 15, wherein the taps among the first group are divided into a first section and a second section, and the method further comprises:
disabling any one tap among the plurality of taps of the first section in a dynamically-configured manner based on channel estimation or an adaptive algorithm; and
disabling any one tap among the plurality of taps of the second section in a predetermined manner according to predicted channel characteristics.

19. The method of claim 15, wherein the sampling interval of the first group is substantially equal to a symbol period of the input signal and the sampling interval of the second group is substantially smaller than the symbol period.

20. The method of claim 13, further comprising:
estimating a channel according to an adaptive algorithm to generate the tap coefficient.
